(19) United States
(12) Patent Application Publication
(10) Pub. No.: US 2026/0092763 A1
(43) Pub. Date: Apr. 2, 2026

(54) DETONATOR WITH INTEGRATED SOLID-STATE FIRESET

(71) Applicant: Excelitas Technologies Corp., Waltham, MA (US)

(72) Inventors: Kenneth Brandmier, Coatesville, PA (US); John Edward Waldron, Coatesville, PA (US)

(73) Assignee: Excelitas Technologies Corp., Waltham, MA (US)

(21) Appl. No.: 18/892,037

(22) Filed: Sep. 20, 2024

Related U.S. Application Data
(60) Provisional application No. 63/584,592, filed on Sep. 22, 2023.

(51) Int. Cl. F42B 3/12; H10D 64/27

(52) U.S. Cl. CPC F42B 3/121; F42B 3/125; H10D 64/518

(57) ABSTRACT

An integrated fireset including a bridge slapper (or exploding via) connected internally to a firing capacitor, flyer material, and solid state switch, the fireset and energetic components encapsulated by a “TO” type transistor package that is hermetically sealed. The integrated fireset may include an integrated switch; a first electrode; a second electrode and separated from the first electrode by the integrated switch; one or more vias configured to electrically couple the integrated switch and a contact region of the second electrode; and a patterned dielectric layer disposed on the contact region.

### CROSS-REFERENCE TO RELATED APPLICATIONS

This application claims the benefit under 35 U.S.C. § 119(e) of U.S. Provisional Patent Application No. 63/584,592 , filed on Sep. 22, 2023, entitled “SOLID-STATE SWITCHED-INITIATOR,” which is hereby incorporated by reference herein in its entirety.

### BACKGROUND

Switched initiators are used to provide on-demand detonation of a primary charge (e.g., an explosive). To detonate a primary charge, the switched initiator rapidly generates a projectile to strike the primary charge and cause detonation. To generate the projectile, a fireset stores energy which may be released on command to quickly transfer energy to an exploding element that, once exploded, propels a projectile towards the primary charge.

### TECHNICAL FIELD

The present disclosure relates generally to the field of energetic material initiation devices and, in particular, to an energetic material initiation device that controls and converts energy into a kinetic shockwave, integrated within a detonator package.

### SUMMARY

Some embodiments provide for an integrated semiconductor device comprising: an integrated switch including a first doped layer and a third doped layer that are separated by a second doped layer, the first and third doped layer having a first doping type, and the second doped layer having second doping type that is opposite from the first doping type; a first metal layer disposed on the first layer and configured as a first electrode; a second metal layer configured as a second electrode and separated from the first metal layer by the integrated switch; an interlayer dielectric layer disposed on the third layer between the integrated switch and the second metal layer; one or more vias configured to electrically couple the integrated switch and a contact region of the second metal layer; and a patterned dielectric layer disposed on the contact region.

In some embodiments, the first doping type is P and the second doping type is an N such that the integrated switch is a PNP transistor.

In some embodiments, the first doping type is N and the second doping type is a P such that the integrated switch is an NPN transistor.

In some embodiments, a first via of the one or more vias, includes a doped cap electrically coupling the via to the integrated switch.

In some embodiments, the doped cap has the second doping type and is more heavily doped than the second layer.

In some embodiments, the interlayer dielectric layer is a first dielectric layer and the integrated semiconductor device further comprises a second interlayer dielectric layer disposed between the first dielectric layer and the second metal layer.

In some embodiments, a first via, of the one or more vias, includes a first metal component disposed in the first dielectric layer and a second metal component having an impedance larger than the first metal layer, wherein the second metal component is disposed in the second dielectric layer, and wherein the second metal component is electrically coupled to the first metal component.

In some embodiments, the second metal component is a metal via.

Some embodiments provide for an integrated semiconductor device comprising: a first integrated circuit including: an integrated switch including a first doped layer and a third doped layer that are separated by a second doped layer the first and third layer having a first doping type, and the second layer having second doping type that is opposite from the first doping type; a first metal layer disposed on the first layer and configured as a first electrode; a second metal layer configured as a second electrode and separated from the first metal layer by the integrated switch; an interlayer dielectric disposed on the third layer between the integrated switch and the second metal layer; one or more vias configured to electrically couple the integrated switch and a contact region of the second metal layer; and a patterned dielectric layer disposed on the contact region; a second integrated circuit including a power supply circuit and a switch control circuit, wherein the power supply circuit is configured to provide power to the first metal layer, and wherein the switch control circuit is configured to conduct control signals for the integrated switch; a capacitor disposed on the first integrated circuit such that a first electrode of the capacitor is coupled to the power supply circuit.

In some embodiments, the first doping type is P and the second doping type is an N such that the integrated switch is a PNP transistor.

In some embodiments, the first doping type is N and the second doping type is a P such that the integrated switch is an NPN transistor.

In some embodiments, the doped cap has the second doping type and is more heavily doped than the second layer.

In some embodiments, the interlayer dielectric layer is a first dielectric layer and the integrated semiconductor device further comprises a second interlayer dielectric layer disposed between the first dielectric layer and the second metal layer.

In some embodiments, a first via, of the one or more vias, includes a first metal component disposed in the first dielectric layer and a second metal component having an impedance resistance larger than the first metal layer, wherein the second metal component is disposed in the second dielectric layer, and wherein the second metal component is electrically coupled to the first metal component.

In some embodiments, the second metal component is a metal via.

Some embodiments provide for an integrated semiconductor device comprising: an integrated switch including a first doped layer and a third doped layer that are separated by a second doped layer, the first and third doped layer having a first doping type, and the second doped layer having second doping type that is opposite from the first doping type; a first metal layer disposed on the first layer and configured as a first electrode; a second metal layer configured as a second electrode and separated from the first metal layer by the integrated switch; an interlayer dielectric layer disposed on the third layer between the integrated switch and the second metal layer; and one or more vias configured to electrically couple the integrated switch and a contact region of the second metal layer.

In some embodiments, a first via of the one or more vias, includes a doped cap electrically coupling the via to the integrated switch.

In some embodiments, the doped cap has the second doping type and is more heavily doped than the second layer.

In some embodiments, the interlayer dielectric layer is a first dielectric layer and the integrated semiconductor device further comprises a second interlayer dielectric layer disposed between the first dielectric layer and the second metal layer.

Some embodiments provide for an integrated fireset or CDU comprising: a high voltage solid state switch; an integrated capacitor; three-dimensional integrated circuit technology (e.g. through silicon vias or multi-chip module wire bonding); a patterned slapper chip or exploding via on the high voltage solid-state switch; a bridge member, a flyer layer extending over the bridge member or the exploding via; and a barrel spacer between the bridge member and energetic material.

In some embodiments, the integrated capacitor is connected to the patterned slapper chip through the three-dimensional integrated circuit technology.

In some embodiments, the bridge is deposited on the high voltage solid-state switch.

In some embodiments, the solid-state switch includes an integrated area configured to produce localized heating and current density to form an exploding via.

### BRIEF DESCRIPTION OF THE DRAWINGS

FIG. 1A is a perspective view of a chip slapper detonator.

FIG. 1B is a side view of an initiation sequence of a chip.

FIG. 2A is a perspective view of a semiconductor switch initiator having a patterned dielectric coating, in accordance with some embodiments.

FIG. 2B is a cross-sectional view of a semiconductor switch initiator through the cathode contact region, in accordance with some embodiments.

FIG. 2C is a perspective view of a second semiconductor switch initiator having a patterned dielectric coating, in accordance with some embodiments.

FIG. 3A is a perspective view of a soldered assembly solid-state switched-initiator, in accordance with some embodiments.

FIG. 3B is a perspective of a solder assembled solid-state switched-initiator, in accordance with some embodiments.

FIG. 4A is an exploded view of the explosive assembly for use with the solid-state switched-initiator assembly, in accordance with some embodiments.

FIG. 4B is a perspective view of the explosive assembly for use with the solid-state switched-initiator assembly, in accordance with some embodiments.

FIG. 5A is a first perspective view of a solid-state switched-initiator packaged detonator, in accordance with some embodiments.

FIG. 5B is a second perspective view of a solid-state switched-initiator packaged detonator, in accordance with some embodiments.

FIG. 5C is a third perspective view of a bottom of a solid-state switched-initiator packaged detonator, in accordance with some embodiments.

FIG. 6 is an exploded view of a complete packaged detonator, in accordance with some embodiments.

FIG. 7A is a perspective view of a complete detonator assembly with a cover, in accordance with some embodiments.

FIG. 7B is a perspective view of the bottom of a complete detonator assembly with a cover, in accordance with some embodiments.

### DETAILED DESCRIPTION

Aspects of the present disclosure provide systems and methods for providing a solid-state switched-initiator for improving the performance of initiators. The improved solid-state switched-initiators efficiently concentrate high-voltages for initiation to reduce the power requirements for initiation.

Detonators are used to detonate a primary charge such as an explosive of an air to surface missile. Such detonators are also used to detonate explosives used in other tactical devices, construction explosives, rocket boosters and the like. These types of detonators are designed to be physically robust and of high integrity. For example, an air to surface missile may be designed to pierce a bunker or other building and then to detonate the primary explosive.

Similarly, a detonator in a down-well application detonates under relatively high temperature and pressure conditions. The detonator, therefore, should survive the shock of launch and impact, as well as elevated pressures and temperatures.

Traditional firing circuits are comprised of relatively large devices in relation to the bridge components, to wit, the metal trace and substrate as described in U.S. Pat. No. 6,234,081

and prior art. The disparity in volume of the high voltage switch and capacitor traditionally requires remoting of the bridge components, energetic materials, and hermetic enclosure of the detonator as described in U.S. Pat. Nos. 6,178,888 and 6,158,347 from the remaining firing circuity.

Within the area of energetics initiation, an electronic fireset, also known as a Capacitor Discharge Unit (CDU) generally includes three separate components connected in series. A high-voltage capacitor; a high-voltage switch, either a spark gap, gas tube, or solid state; and an Exploding foil initiator (“EFI”) or Low Energy Exploding Foil Initiator (LEEFI).

EFI detonators, (e.g. “chip slappers”) generally include a ceramic chip upon which is deposited two opposing conductive metal lands (typically copper) which taper to a narrow “bridge” portion therebetween. An electrical current is provided to the lands at the time of initiation and the bridge bursts sending a flying plate thereon into an explosive charge, which, in turn, detonates the primary charge.

EFI detonators require an energy source and a rapid discharge of the resultant energy in that source across the narrow bridge portion of the EFI. The amount of energy utilized to burst the bridge is proportional to the impedance of the bridge in relation to the total impedance of the firing circuit, which consists of a high voltage capacitor, EFI bridge, and a high voltage switch.

In an EFI circuit, the High Voltage (HV) capacitor stores energy (½ CV2) until the HV switch is turned on. At that time, the capacitor's charge (C*V) is rapidly passed through the HV switch as (I*T) and the EFI's conductive foil in the form of rapidly increasing current. The rate of change of the current, (di/dt) is dictated by the circuit voltage, decreasing, divided by the total circuit inductance (V/L). As a result of the current passing through the foil, an increasing voltage is developed across the foil's inherent resistance, resulting in a rapid and extreme increase in temperature. This rapid increase in temperature rapidly transitions the conductive foil from a solid to a liquid, to a gas, and finally to an energized plasma. Following the generation of the energized plasma, the current flow through the plasma decays. However, the decaying current flow further energizes and heats the plasma. The resultant heating and rapid volumetric expansion induce pressure on the dielectric coating covering the foil. This coating expands in a bubble until the pressure becomes great enough to shear a prescribed portion of the coating away and propels it at a sufficient velocity toward an explosive pellet to initiate the explosive train.

The configuration of a fireset is to store energy, and then on command, quickly and efficiently transfer enough energy from the storage capacitor to the “exploding element” to heat it quickly enough to transform it from a solid to an energized plasma with sufficient energy to produce the desired increase in trapped pressure leading to an abrupt expulsion of a piece of material known as a “flyer”in the direction of an insensitive explosive.

The inventors have recognized and appreciated that in the conventional three component configuration, any energy consumed/dissipated by the HV switch, the capacitor/s Equivalent Series Resistance (ESR), or other parasitic impedance is not used for the intended purpose; thus, the parasitic impedance is considered a loss of efficiency. These inefficiencies may be offset by increasing the power capacity of the system power source to supply and store additional energy to offset the loss. However, increasing the power capacity of the system power increases the size, capability, and the cost of the storage capacitor as well as other related charging circuitry. For some configurations, the charge dissipated across the bridge may be as high as 40 percent of the total charge.

The inventors have further appreciated that HV switches, specifically semiconductor switches, are configured so that when the switch is turned on, the switch will slew as quickly as possible and present as low an impedance as possible to enable the energy transfer through the switch to the load as efficiently as possible by minimizing losses from the switch. However, the inventors have recognized that for the purpose of initiating an explosive train (e.g., explosive sequence), where the entire circuit and the switch itself will be destroyed the first time the ENTIRE system is used. Accordingly, the switch does not need to be efficient with regard to the impedance of the switch. Rather, the switch needs to be designed to block the necessary voltage when off (preventing current flow). It will, when switched on, allow the appropriate current flow, and switches with larger impedance may provide improved current blocking. While the switch impedance is usually considered detrimental to performance, the inventors have recognized that the heat generated from the impedance of the switch may contribute to producing the appropriate heating, rapidly enough, to cause rapid expansion of the dielectric and expel a “flyer”having sufficient mass and velocity to excite the explosive pellet.

Previous art has described an integrated detonator and Fireset components with a smaller size as described in U.S. Pat. No. 8,091,477. While this integrated detonator reduces the total size and increases the efficiency of the resultant circuit, it does not facilitate a fully integrated Fireset in the hermetic enclosure and remains composed of discrete components.

Accordingly, the inventors have developed a solid-state switched-initiator that combines the functionality of an HV switch and an EFI/LEEFI into a single component. By integrating the two components to utilize heat generated through the switch as part of the ignition sequence, the size reducing, the size and packaging costs, energy in the form of heat previously lost to the “turn-on switching loss (EON)” and “on-state voltage drop (VTM)” of the HV switch is now used to aid in heating, vaporization, and eventual ionization of a localized portion near the surface of the semiconductor component. This portion is coated with a dielectric material (Polyimide or other) designed to react in a similar fashion to the foil bridge and dielectric coating used in the conventional EFI/LEEFI.

According to one aspect of the present technology, the initiator provides an improved bridge slapper or exploding via type detonator on the HV switch and collocated with the capacitor, effectively producing a compact, closed loop fireset.

According to one aspect of the present technology, the imitator provides such an improved detonator which remains physically robust and able to withstand violent environmental conditions.

According to one aspect of the present technology, the initiator provides an improved detonator which requires less energy than previous discrete designs while maintaining a high safety factor.

A further aspect of the present technology is reduce part to part variability by integrating fireset components and the bridge slapper or exploding via portion of the detonator into the same substrate.

According to one aspect of the present technology, the solid-state switched-initiator does not require an external firing circuit to operate the bridge slapper type detonator.

Aspects of the present technology feature a detonator comprising a base portion including a Solid-State Switched-Initiator, a low equivalent series inductance and resistance capacitor, a bridge slapper type EFI member or exploding via on that switch substrate, a barrel connector, an energetic loaded sleeve, a tube to receive said sleeve over the semiconductor, and a welded cover.

More broadly, this initiator features a bridge slapper or exploding via comprising a substrate of high voltage switch, and high voltage, low equivalent series resistance and inductance capacitor. Therefore, according to one aspect of the present technology, there is no external fireset required for the hermetic detonator described herein. Therefore, the substrate will maintain a rectangular shape and either utilize a shaped bridge member as described in U.S. Pat. No. 6,234,081, a conventional rectangular shaped bridge member, or an exploding via.

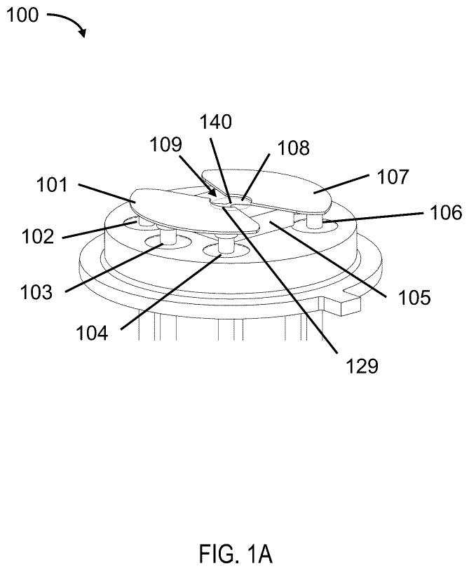

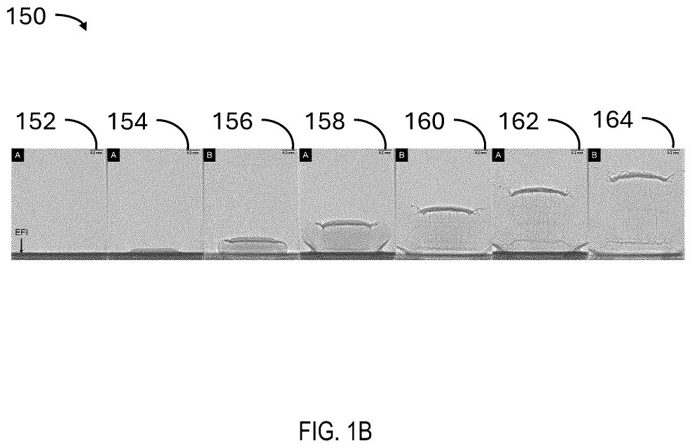

FIG. 1A is a perspective view of a chip slapper detonator 100. Slapper 100 includes a ceramic substrate 5 upon which a metal film is deposited to provide conductive lands for a rectangular bridge. The metal film is formed of a conductive metal, such as copper, that is etched into first and second conductive lands 108 and 129, respectively. The rectangular bridge member 140 extends between the first and second conductive lands. Slapper 100 further includes a flyer layer is disposed over bridge member 140 at position 109. The flyer may be, for example, a dielectric coating such as polyimide or “Kapton.”

When configured for use, lands 101 and 107 are connected to a suitable voltage source through pads 102, 103, 104, 106, and 108 such that when several thousands of Volts are applied to the lands, bridge member 40 vaporizes and is turned into a plasma. This plasma accelerates a portion of the flyer layer (“the flying plate”) at position 109 away from substrate 105 and towards an explosive. The shock of the flying plate striking the explosive detonates the explosive.

Another conventional rectangular bridge member slapper is shown in U.S. Pat. No. 4,862,803 which is hereby incorporated herein by reference in its entirety.

FIG. 1B is a side view of an initiation sequence 150 of a chip. Initiation sequence 150 includes a first frame 152, prior to the start of the initiation sequence. Following the start of the initiation sequence, frame 154 shows the separation of a flier from the substrate. Progressing from frame 156 to frames 158, 160, 162, and 164—the flier is propelled away from the substrate as the plasma, generated during the initiation sequence, expands and accelerates the flier. The initiation sequences frames demonstrate the expansion, shearing, and propulsion of the dielectric coating as a conventional EFI or LEEFI is activated.

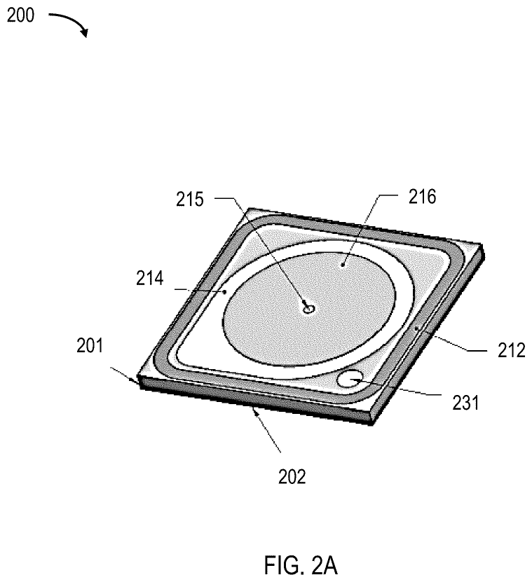

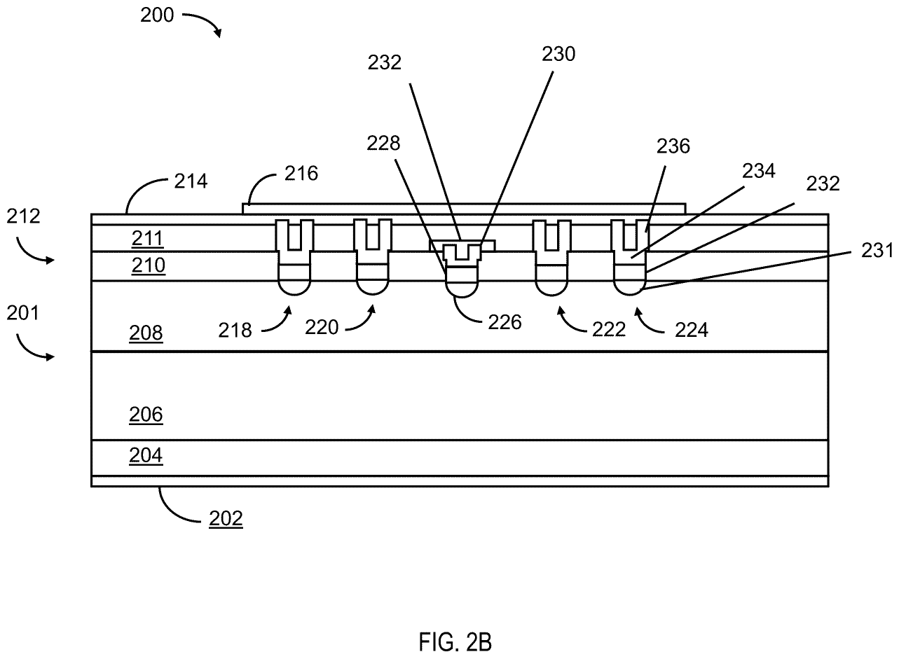

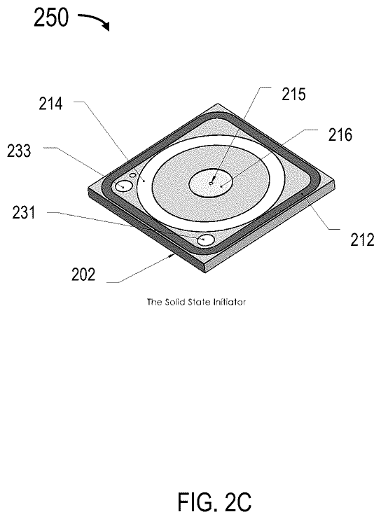

FIG. 2A is a perspective view of a semiconductor switch initiator 200 having a patterned dielectric coating, in accordance with some embodiments. Semiconductor switch initiator 200 integrates a high-voltage switch with an initiating component and flyer to utilize the heat generated when current flows through the switch to explode the initiating component and propel the flyer. In the embodiment of FIG. 2A, the initiating component is integrated with one of the electrodes separated by the switch. The initiation component is configured such that when the switch is closed and current flows through the switch, the initiation component of the electrode is vaporized and propels a flier.

Semiconductor switch initiator 200 includes a high-voltage switch. The high-voltage switch includes doped semiconductor layers 201 and junction termination layer 212. The doped semiconductor layers 201 and junction termination layer 212 are configured to function as a high-voltage transistor switch. The junction termination layer includes the gate circuity to control the transistor switch.

The semiconductor switch initiator 200 is configured between a first electrode 202 and a second electrode 214. In the example of FIG. 2A, first electrode 202 is an anode and second electrode 214 is a cathode. The second electrode 214 is configured with a cathode contact region 215 as the initiation component. In other embodiments, the anode and cathode may be swapped. When the electrodes are swapped, the configuration of the transistor is changed such that the current flow is reversed.

A flier 216 is disposed on the second electrode 214 and configured to be propelled upon vaporization of the cathode contact region 215. The cathode contact region 215 is configured to have an increased impedance relative to the anode and relative to the portion of the cathode coupled to a power source. Accordingly, when the current passes through the cathode contact region, the cathode contact region is heated. When the power is high enough, the cathode contact region is vaporized into a plasma which expands and propels the flier away from the semiconductor switch. Although the embodiment of FIG. 2A includes a cathode contact region and a flier disposed on the second electrode, other examples, may be configured to include an anode contact region, instead of a cathode contact region and may be accordingly configured with the flier disposed on the anode.

The flier 216 is configured as a semiconductor having a patterned dielectric coating. In the example of FIG. 2A the patterned dielectric coating is circular and centered around the cathode contact region 215. In some embodiments, the semiconductor switch initiator 200 includes a single contact region, such as in FIG. 2A. In some embodiments, the semiconductor switch initiator 200 includes multiple contact regions. For example, the semiconductor switch

initiator may have between 2 and 100 contact regions. When the semiconductor switch has multiple contact regions, the contact regions may be configured to generate more heat near the center of the flier. In some examples, the multiple contact regions may be configured symmetrically around the center of the flier.

Unlike initiators that include separate discrete components, a high-voltage semiconductor switch initiator, such as those designed herein, are configured to reduce parasitic losses, such that the current entering the devices back-side is: (1) made to exit at a much smaller top-side location (e.g., at the cathode contact region); and (2) made to cause rapid and localized heating intense enough to transition the conductive vias and nearby metals into a plasma when the proper amount of charge is transferred through it.

In some embodiments, the transistor is configured as a bipolar junction transistor. In some embodiments, the transistor is configured as a MOSFET transistor.

FIG. 2B is a cross-sectional view of a semiconductor switch initiator 200 through the cathode contact region, in accordance with some embodiments. The semiconductor switch initiator 200 components are configured is the same way as described above in connection with FIG. 2A. The doped semiconductor layers 201 are disposed between electrode 202 and junction termination layer 212. The doped semiconductor layers 201 and junction termination layer 212 are configured as a transistor switch. In the example of FIG. 2B, the bottom-doped semiconductor layer 204 has P-type doping. The middle-doped semiconductor layer 206 has N-type doping. The top-doped semiconductor layer 208 has P-type doping. The junction termination layer 212 includes two interlayer dielectric layers 210 and 212, respectively. The bottom interlayer dielectric layer 210 is disposed on the top-doped semiconductor layer 208. The top interlayer dielectric layer 211 is disposed between the bottom interlayer dielectric layer and the second electrode 214. The junction termination layer includes conductive paths to electrically couple the second electrode 214 to the top-doped semiconductor layer 208. The junction termination layer 212 includes gate circuitry to control whether current passes through the doped-semiconductor layers from the first electrode 202 to the second electrode 214.

The gate circuity includes a conductive via coupling a doped semiconductor cap 226 to a metal gate trace 232. The metal gate trace 232 is patterned through the top interlayer dielectric layer 211 and electrically coupled to gate pad 231, shown in FIG. 2A. As shown in the example of FIG. 2B, the metal via includes a metal pad 228 and metal via 230.

In some embodiments, the doped semiconductor cap 226 is P-Type doped. The doped semiconductor cap 226 may be heavily P-doped such that the P-doping of the doped semiconductor cap 226 is more heavily doped than the P-type doping of the top-doped semiconductor layer 208. In some embodiments, the bottom-doped semiconductor layer 204 is also heavily P-doped. For example, the P-type doping of the bottom-doped semiconductor layer 204 is the same level of doping as the doped semiconductor cap 226. As another example, the P-type doping of the bottom-doped semiconductor layer 204 may be a different level of doping as the doped semiconductor cap 226.

The conductive paths, electrically coupling the second electrode 214 to the top-doped semiconductor layer 208, are positioned to electrically couple to the cathode contact region of the electrode 215. Patterned dielectric coating 216 is disposed above the cathode contact region. In the example of FIG. 2B, the conductive paths include conductive vias 218, 220, 222, and 224. The conductive vias include doped semiconductor caps 231, metal pad 232, conductive filed via portion 234, and insulator filed via portion 236.

In some embodiments, the doped semiconductor caps 231 are N-type doped. The doped semiconductor caps may be heavily N-doped such that the N-doping of the doped semiconductor caps 231 is more heavily doped than the N-type doping of the middle-doped semiconductor layer 206.

FIG. 2C is a perspective view of a second semiconductor switch initiator 250 having a patterned dielectric coating, in accordance with some embodiments. Semiconductor switch initiator 250 includes doped semiconductor layers 202, patterned dielectric coating 216, second electrode 214, cathode contact region 215, gate pad 231, and return gate pad 233. The semiconductor switch initiator 250 is configured in the same way as semiconductor switch initiator 200 with respect to the doped semiconductor layers 202, patterned dielectric coating 216, junction termination layer 212, second electrode 214, and cathode contact region 215. The gate of semiconductor switch initiator 250 is configured with a gate pad 231 and a gate return pad 233. The junction termination layer uses a high surface are to distribute the electric field to support larger voltages with less physical clearance.

In some embodiments, the doped semiconductor layers 202 may be doped silicon layers. In some embodiments, the semiconductor layer may include a silicon carbide layer. In some embodiments, other semiconductors may be used, as aspects of the technology described herein are not limited in this respect.

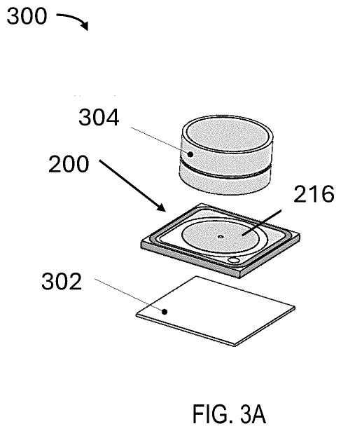

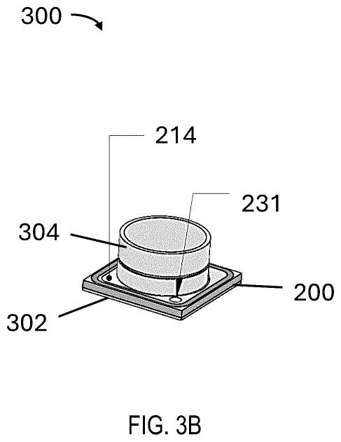

FIG. 3A is a perspective view of a soldered assembly solid-state switched-initiator 300, in accordance with some embodiments. The assembly is configured to structurally support the switch such that upon initiation, the forces on the flier result in a trajectory of the flier towards a primary charge. Soldered assembly solid-state switched-initiator 300 includes a semiconductor switch initiator 200, a tamper 302, and a cathode connector 304.

The tamper is configured to support the back of the switch (e.g., the side opposite the flier) such to reinforce the device from the forces exerted down upon the switch. In some embodiments, the tamper is a nickel clad molybdenum material. The nickel clad molybdenum tamper matches the coefficient of thermal expansion of the semiconductor and serves to ruggedized it as well as mechanically reinforce the semiconductor during the firing event. In some embodiments, other materials that are configured with a similar coefficient of thermal expansion as the semiconductor switch may be used.

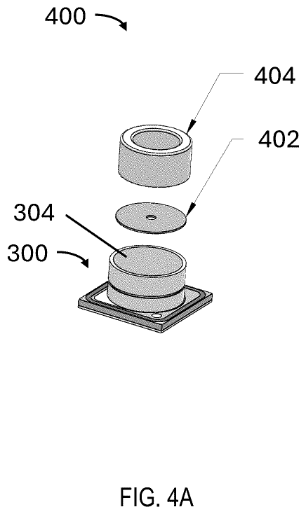

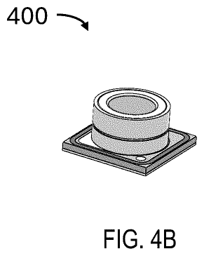

The cathode connector 304 is shaped to be connected to the cathode to form an electrical coupling with the cathode. In some embodiments, the cathode connector 304 is cylindrical such that it fits around the circular flier 216 and forms a cavity above the cathode contact region. Accordingly, the cathode connector 304 will not obscure the trajectory of the flier 216 upon initiation. In some embodiments, the cathode connector is configured to support a barrel (see FIG. 4) to guide the trajectory of the flier 216.

In some embodiments, the cathode connector is a nickel-cobalt ferrous alloy material. For example, the cathode connector may be KOVAR In some embodiments, another material that has a coefficient of thermal expansion matched to the semiconductor switch may be used, such that the size does not vary significantly during the initiation process.

FIG. 3B is a perspective of a solder assembled solid-state switched-initiator 300, in accordance with some embodiments. As assembled, the assembly includes switch initiator 200 disposed on tamper 302, and cathode connector 304 disposed on electrode 214 such that the cathode connector 304 is electrically coupled to the electrode 214. The Kovar cathode connector closely matches the coefficient of thermal expansion of the semiconductor. When soldered to the semiconductor, using high-temperature solder, it hermetically seals one end of the Kovar cathode connector to the semiconductor, as shown in FIG. 3B. In some embodiments, where the gate contact is on the top of the assembly, the positioning of the cathode connector 304 does not obscure the gate contact 231, such that external signals may be applied to control the gate of the switch initiator 200.

FIG. 4A is an exploded view of the explosive assembly for use with the solid-state switched-initiator assembly, in accordance with some embodiments. The cathode connector 304, solder assembled solid-state switched-initiator 300, is shaped to receive and support barrel 402 to direct the flier towards an explosive sleeve 404.

The barrel 402 is circular such that it may be inserted into the center of the cathode connector 304. In some embodiments, the barrel is a nickel-cobalt ferrous allow material. For example, the cathode connector may be Kovar®. Accordingly, the barrel thermal expansion is matched to that of the cathode connector, such that the barrel diameter may be matched to the diameter of the cathode connector and secured therein.

The explosive sleeve 404 is shaped to be inserted into the cathode connector 304. Accordingly, the cathode connector secures the explosive sleeve 404 in place above the barrel 402. Accordingly, the flier is directed through the barrel 402 into the explosive sleeve 404 upon initiation. To complete the hermetic seal around of the chamber within the cathode connector 304, a welded cap is added to seal the top of the cathode connector with the barrel and explosive sleeve within.

FIG. 4B is a perspective view of the explosive assembly for use with the solid-state switched-initiator assembly, in accordance with some embodiments. In the example of FIG. 4B, the assembled package, with the barrel and explosive sleeve inserted into the cathode connector, is configured with each component having a circular cross section. However, in other embodiments, the components may have different cross-sectional shapes, as aspects of the technology described herein are not limited in this respect.

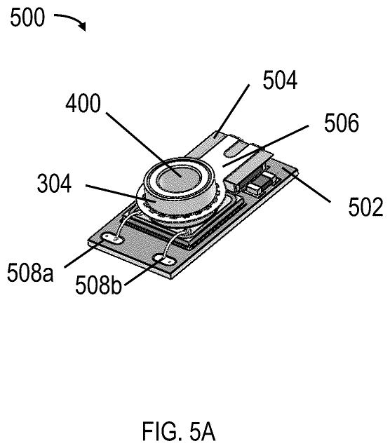

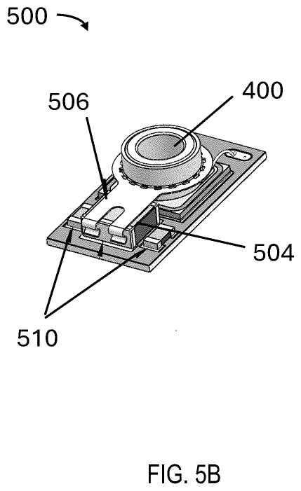

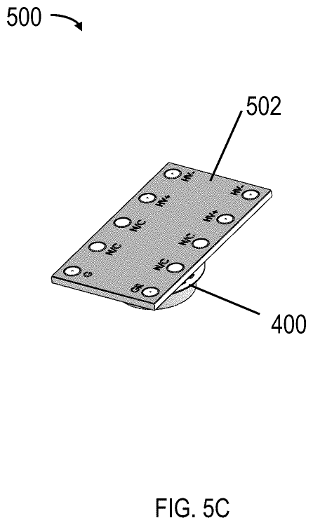

FIG. 5A is a first perspective view of a solid-state switched-initiator packaged detonator 500, in accordance with some embodiments. The packaged detonator includes explosive assembly 400 bonded to integrated circuit substrate 502. Integrated circuit substrate 502 is a printed circuit board having conductive traces to couple a power supply to an anode of the explosive assembly 400. A power supply 504 is disposed on the integrated circuit substrate 502 adjacent to the explosive assembly 400. A cathode connection lug is disposed over the cathode connector to electrically couple the cathode connector 304 to the power supply.

In some embodiments, the power supply 504 is a capacitor. The capacitor is electrically coupled to the integrated circuit substrate 502 through an electrical pad. The capacitor is further electrically coupled to the cathode connection lug. Accordingly, the capacitor discharges through the switch when the switch is closed, causing the cathode to heat.

To control the switch of the explosive assembly 400, bond wires 508a and 508b are included to conduct control signals carried through the integrated circuit substrate 502 to the gate electronics. In some embodiments, the bone wires 508a and 508b are aluminum bond wires. In some embodiments, other bonding materials may be used, as aspects of the technology described herein are not limited in this respect.

FIG. 5B is a second perspective view of a solid-state switched-initiator packaged detonator 500, in accordance with some embodiments. The detonator package 500 includes explosive assembly 400 and power supply 504. The power supply and explosive assembly are electrically coupled through the integrated circuit substrate 502 and the cathode connection lug 506. As shown in FIG. 5B, the cathode connection lug includes clips for connecting and maintaining contact with the capacitor 504. The detonator package 500 further includes bleed resistors 510.

FIG. 5C is a third perspective view of a bottom of a solid-state switched-initiator packaged detonator, in accordance with some embodiments. The bottom of integrated circuit substrate 502 includes electrical contacts for coupling signals through traces in the integrated circuit substrate. The electrical contacts include contacts for receiving control signals configured to operate the switch of explosive assembly 400. The electrical contacts also include a grounding contact.

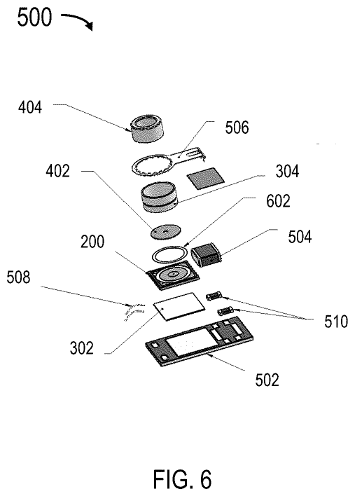

FIG. 6 is an exploded view of a complete packaged detonator, in accordance with some embodiments. The packaged detonator 500 includes integrated circuit substrate 502, bleed resistors 510, aluminum bond wires 508, tamper with high temperature solder 302, solid-state switched-initiator 200, power source 504, high temperature solder preform 602, barrel 402, cathode connector 304, cathode connection lug 506, and explosive sleeve 404.

The integrated circuit substrate 502 may be any suitable printed circuit board that fits the solid-state switch and the capacitor. The printed circuit board includes conductive pads on the surface configured to contact the solid-state switch and an electrode of the capacitor. As an example, the printed circuit board may be a standard printed circuit board made from ISOLAB high temperature prepreg.

The tamper 302 is disposed between the solid-state switch and the conductive pad of the printed circuit board. The tamper provides strain relief and reinforcement to the exploding switch. The tamper 302 includes pre-deposited high-temperature solder for electrically coupling the tamper to the solid-state switch.

Power source 504 is coupled to the integrated circuit substrate 502 to provide power to cause the initiation when the switch is closed. In some embodiments, the power source 504 is a reduced-size firing capacitor. The capacitor may use a lower voltage version than with an ESR due to the effective use of power by the packaged detonator 500 to cause the initiation.

To form a hermetic seal, high temperature solder preform 602 is applied between the cathode connector 304 and the solid-state switched-initiator 200. Within the cavity of the cathode connector 304, the barrel 402 and exploding sleeve 404 are inserted. In some embodiments, the exploding sleeve is a Blue Chip® sleeve. After the sleeve is assembled into the cathode connector, the pressed energetics can be capped. The cathode connector 304 includes a snap groove for securing the cathode connection lug 506.

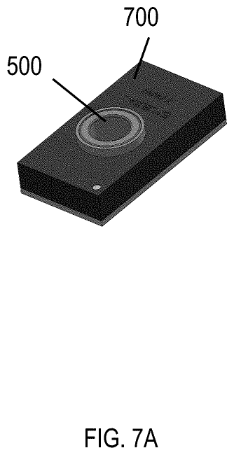

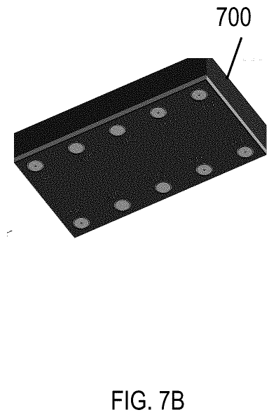

FIG. 7A is a perspective view of a complete detonator assembly with a cover, in accordance with some embodiments. The packaged detonator 500 is covered by cover 700. Cover 700 is an insulating housing configured to seal the electronic components from the environment. The cover 700 includes an aperture through which the explosive sleeve may be unobstructed.

FIG. 7B is a perspective view of the bottom of a complete detonator assembly with a cover, in accordance with some embodiments. The cover encapsulates the electronics from the top side of the detonator. Accordingly, the electrical contacts on the bottom are accessible for installation of the detonator in a device.

Having thus described several aspects of at least one embodiment, it is to be appreciated that various alterations, modifications, and improvements will readily occur to those skilled in the art. Such alterations, modifications, and improvements are intended to be part of this disclosure and are intended to be within the spirit and scope of the principles described herein. Accordingly, the foregoing description and drawings are by way of example only.

The phrase “and/or,” as used herein in the specification and in the claims, should be understood to mean “either or both,” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B,” when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

The indefinite articles “a” and “an,” as used herein in the specification and in the claims, unless clearly indicated to the contrary, should be understood to mean “at least one.”

As used herein in the specification and in the claims, the phrase, “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently, “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “substantially,” “approximately,” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

All definitions, as defined and used herein, should be understood to control over dictionary definitions, definitions in documents incorporated by reference, and/or ordinary meanings of the defined terms.

1. An integrated semiconductor device comprising:
an integrated switch including a first doped layer and a third doped layer that are separated by a second doped layer, the first and third doped layer having a first doping type, and the second doped layer having second doping type that is opposite from the first doping type;
a first metal layer disposed on the first layer and configured as a first electrode;
a second metal layer configured as a second electrode and separated from the first metal layer by the integrated switch;
an interlayer dielectric layer disposed on the third layer between the integrated switch and the second metal layer;
one or more vias configured to electrically couple the integrated switch and a contact region of the second metal layer; and
a patterned dielectric layer disposed on the contact region.

2. The integrated semiconductor device of claim 1, wherein the first doping type is P and the second doping type is N such that the integrated switch is a PNP transistor.

3. The integrated semiconductor device of claim 1, wherein the first doping type is N and the second doping type is P such that the integrated switch is an NPN transistor.

4. The integrated semiconductor device of claim 1, wherein a first via of the one or more vias, includes a doped cap electrically coupling the via to the integrated switch.

5. The integrated semiconductor device of claim 4, wherein the doped cap has the second doping type and is more heavily doped than the second layer.

6. The integrated semiconductor device of claim 1, wherein the interlayer dielectric layer is a first dielectric layer and the integrated semiconductor device further comprises a second interlayer dielectric layer disposed between the first dielectric layer and the second metal layer.

7. The integrated semiconductor device of claim 6, wherein a first via, of the one or more vias, includes a first metal component disposed in the first dielectric layer and a second metal component having an impedance larger than the first metal layer, wherein the second metal component is disposed in the second dielectric layer, and wherein the second metal component is electrically coupled to the first metal component.

8. The integrated semiconductor device of claim 7, wherein the second metal component is a metal via.

9. An integrated semiconductor device comprising:
a first integrated circuit including:
an integrated switch including a first doped layer and a third doped layer that are separated by a second doped layer the first and third layer having a first doping type, and the second layer having second doping type that is opposite from the first doping type;
a first metal layer disposed on the first layer and configured as a first electrode;
a second metal layer configured as a second electrode and separated from the first metal layer by the integrated switch;
an interlayer dielectric disposed on the third layer between the integrated switch and the second metal layer;
one or more vias configured to electrically couple the integrated switch and a contact region of the second metal layer; and
a patterned dielectric layer disposed on the contact region;
a second integrated circuit including a power supply circuit and a switch control circuit, wherein the power supply circuit is configured to provide power to the first metal layer, and wherein the switch control circuit is configured to conduct control signals for the integrated switch;
a capacitor disposed on the first integrated circuit such that a first electrode of the capacitor is coupled to the power supply circuit.

10. The integrated semiconductor device of claim 9, wherein the first doping type is P and the second doping type is N such that the integrated switch is an PNP transistor.

11. The integrated semiconductor device of claim 9, wherein the first doping type is N and the second doping type is P such that the integrated switch is an NPN transistor.

12. The integrated semiconductor device of claim 9, wherein a first via, of the one or more vias, includes a doped cap electrically coupling the via to the integrated switch.

13. The integrated semiconductor device of claim 12, wherein the doped cap has the second doping type and is more heavily doped than the second layer.

14. The integrated semiconductor device of claim 9, wherein the interlayer dielectric layer is a first dielectric layer and the integrated semiconductor device further comprises a second interlayer dielectric layer disposed between the first dielectric layer and the second metal layer.

15. The integrated semiconductor device of claim 14, wherein a first via, of the one or more vias, includes a first metal component disposed in the first dielectric layer and a second metal component having an impedance resistance larger than the first metal layer, wherein the second metal component is disposed in the second dielectric layer, and wherein the second metal component is electrically coupled to the first metal component.

16. The integrated semiconductor device of claim 15, wherein the second metal component is a metal via.

17. An integrated semiconductor device comprising:
an integrated switch including a first doped layer and a third doped layer that are separated by a second doped layer, the first and third doped layer having a first doping type, and the second doped layer having second doping type that is opposite from the first doping type;
a first metal layer disposed on the first layer and configured as a first electrode;
a second metal layer configured as a second electrode and separated from the first metal layer by the integrated switch;
an interlayer dielectric layer disposed on the third layer between the integrated switch and the second metal layer; and
one or more vias configured to electrically couple the integrated switch and a contact region of the second metal layer.

18. The integrated semiconductor device of claim 17, wherein a first via of the one or more vias, includes a doped cap electrically coupling the via to the integrated switch.

19. The integrated semiconductor device of claim 18, wherein the doped cap has the second doping type and is more heavily doped than the second layer.

20. The integrated semiconductor device of claim 17, wherein the interlayer dielectric layer is a first dielectric layer and the integrated semiconductor device further comprises a second interlayer dielectric layer disposed between the first dielectric layer and the second metal layer.
